(19) United States
(12) Patent Application Publication
(10) Pub. No.: US 2017/0262126 A1
(43) Pub. Date: Sep. 14, 2017

(54) DISPLAY SUBSTRATE, METHOD FOR MANUFACTURING THE SAME AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Shengji YANG, Beijing (CN); Xue DONG, Beijing (CN); Hailin XUE, Beijing (CN); Xiaochuan CHEN, Beijing (CN); Haisheng WANG, Beijing (CN); Yingming LIU, Beijing (CN); Xiaoliang DING, Beijing (CN); Weijie ZHAO, Beijing (CN); Hongjuan LIU, Beijing (CN)

(21) Appl. No.: 15/529,892

(22) PCT Filed: Oct. 13, 2016
(86) PCT No.: PCT/CN2016/101971

§ 371 Date: May 25, 2017

(30) Foreign Application Priority Data
Oct. 30, 2015 (CN) 201510729572.8

(51) Int. Cl. G06F 3/041; G06F 3/044; G02F 1/1362; H01L 27/32; G02F 1/1333; G02F 1/1368

(52) U.S. Cl. CPC G06F 3/0416; G02F 1/13338; G02F 1/1368; G02F 1/136286; H01L 27/323; H01L 27/3276; G06F 3/044; G06F 3/0412; H01L 2227/323; G06F 2203/04103; G06F 2203/04105

(57) ABSTRACT

A display substrate, a method for manufacturing the display substrate and a display device are provided. The display substrate includes a basal substrate; a first electrode disposed on the basal substrate, the first electrode being deformable; a middle frame disposed on a side of the basal substrate departing from the first electrode; and a second electrode disposed between the middle frame and the basal substrate, forming a capacitor with the first electrode; the capacitance of the capacitor being variable based on deformation of the first electrode. According to the solution of the embodiments, the second electrode is arranged on the middle frame. The first electrode and the second electrode form a capacitor as a pressure sensor. Therefore, the pressure sensor can be integrated into the display substrate, and the space occupied by the pressure sensor in the display substrate is reduced.

### RELATED APPLICATIONS

The present application is the U.S. national phase entry of the international application PCT/CN2016/101971, with an international filing date of Oct. 13, 2016, which claims the benefit of Chinese Patent Application No. 201510729572.8, filed on Oct. 30, 2015, the entire disclosures of which are incorporated herein by reference.

### TECHNICAL FIELD

The present disclosure relates to the field of display technology, in particular to a display substrate, a method for manufacturing the display substrate and a display device.

### BACKGROUND

OLED (organic light emitting diode) display is one of the hot spots in today's flat panel display research. Compared with the liquid crystal display, OLED display has the advantages of low power consumption, low production cost, self-luminous, wide viewing angle and fast response. At present, OLED display has begun to replace the traditional LCD display in the mobile phone, PDA, digital camera and other display fields. Pixel drive circuit design is the core technical content of OLED display, which has important research significance.

Pressure sensing technology refers to the technology that can detect external forces. This technology was used in industrial control, medical treatment and other fields long ago. Driven by the Apple Inc., many manufacturers are looking for suitable solutions to achieve pressure sensing in the display field, especially in the mobile phone or tablet field, which will allow customers to get better human-computer interaction experience. However, at present, this is realized by adding additional mechanisms to the backlight or middle frame portion. This design needs to modify the structural design of the display substrate, and the detection accuracy of this design is limited due to the large assembly tolerance.

### SUMMARY

Therefore, it is desired to integrate the pressure sensing function into the OLED module to achieve better detection accuracy and more optimized cost.

To this end, an embodiment of the disclosure provides a display substrate. The display substrate includes a basal substrate, a first electrode, a middle frame and a second electrode. The first electrode is disposed on the basal substrate, and the first electrode is deformable. The middle frame is disposed on a side of the basal substrate departing from the first electrode. The second electrode is disposed between the middle frame and the basal substrate, forming a capacitor with the first electrode. The capacitance of the capacitor is variable based on deformation of the first electrode.

In certain exemplary embodiments, the display substrate further includes an organic light emitting device and a thin film transistor for driving the organic light emitting device disposed on the basal substrate.

The organic light emitting device includes a bottom electrode layer and a top electrode layer. The thin film transistor includes a first gate layer, a second gate layer and a source-drain layer. The first electrode is formed in the same layer with any one of the first gate layer, the second gate layer, the source-drain layer and the bottom electrode layer.

In certain exemplary embodiments, the display substrate further includes a liquid crystal layer disposed on the basal substrate. A thin film transistor, a pixel electrode layer and a common electrode layer for controlling the liquid crystal layer are disposed on the basal substrate. The thin film transistor includes a gate layer and a source-drain layer. The first electrode is formed in the same layer with any one of the gate layer, the source-drain layer and the pixel electrode layer.

In certain exemplary embodiments, the first electrode and the second gate layer are formed in the same layer.

In certain exemplary embodiments, the first electrode includes a plurality of first electrode subunits. Each first electrode subunit has a grid shape.

In certain exemplary embodiments, the second electrode includes a plurality of second electrode subunits. Each second electrode subunit has the same area and shape as a corresponding first electrode subunit.

In certain exemplary embodiments, the first electrode further includes a plurality of signal transmission lines connected with the plurality of first electrode subunits in one-to-one correspondence. The signal transmission lines are disposed in the same layer with the first electrode and extend along a first direction. The areas of the first electrode subunits gradually decrease along the first direction, thereby providing layout space for the signal transmission lines.

In certain exemplary embodiments, the first electrode further includes a plurality of signal transmission lines connected with the plurality of first electrode subunits in one-to-one correspondence. The signal transmission line and the first electrode are in different layers. The plurality of first electrode subunits have the same area and the same shape.

In certain exemplary embodiments, the display substrate further includes a processing unit generating a touch control signal based on a capacitance variation of the capacitor.

An embodiment of the present disclosure further provides a display device. The display device includes the display substrate according to any one of the above mentioned embodiments.

An embodiment of the present disclosure provides a method for manufacturing a display substrate. The method includes: forming a first electrode on a basal substrate, the first electrode being deformable; and forming a second electrode on a middle frame; arranging the basal substrate with the first electrode on a side of the middle frame on which the second electrode is formed, thereby forming a capacitor with the first electrode and the second electrode.

In certain exemplary embodiments, the method further includes forming an organic light emitting device and a thin film transistor for driving the organic light emitting device on the basal substrate. The organic light emitting device includes a bottom electrode layer and a top electrode layer. The thin film transistor includes a first gate layer, a second gate layer and a source-drain layer. The step of forming the first electrode includes: forming the first electrode when forming any one of the first gate layer, the second gate layer, the source-drain layer and the bottom electrode layer.

In certain exemplary embodiments, the method further includes forming a thin film transistor, a pixel electrode layer and a common electrode layer on the basal substrate for controlling a liquid crystal layer. The thin film transistor includes a gate layer and a source-drain layer. The step of forming the first electrode includes: forming the first electrode when forming any one of the gate layer, the source-drain layer and the pixel electrode layer.

In certain exemplary embodiments, the step of forming the first electrode includes forming a plurality of first electrode subunits. The step of forming the second electrode includes forming a plurality of second electrode subunits. The positions of the second electrode subunits are one-to-one corresponding to the positions of the first electrode subunits.

In certain exemplary embodiments, the step of forming the first electrode includes forming a plurality of second electrode subunits with grid shapes.

In certain exemplary embodiments, the method further includes: in a layer different from the first electrode subunits, forming a plurality of signal transmission lines connected with the plurality of first electrode subunits in one-to-one correspondence. The step of forming the first electrode further includes forming the plurality of first electrode subunits having the same area and the same shape.

In certain exemplary embodiments, the method further includes: forming a plurality of signal transmission lines in the same layer with the first electrode subunits. The plurality of signal transmission lines are connected with the plurality of first electrode subunits in one-to-one correspondence and extend along a first direction. The step of forming the first electrode further includes forming the plurality of first electrode subunits. The areas of the first electrode subunits gradually decrease along the first direction, thereby providing layout space for the signal transmission lines.

According to the solution of the embodiments, the second electrode is arranged on the middle frame. The first electrode and the second electrode form a capacitor as a pressure sensor. Therefore, the pressure sensor can be integrated into the display substrate, and the space occupied by the pressure sensor in the display substrate is reduced.

### BRIEF DESCRIPTION OF THE DRAWINGS

In order to more clearly illustrate the technical solutions in embodiments of the disclosure or in the prior art, the appended drawings needed to be used in the description of the embodiments or the prior art will be introduced briefly in the following. Obviously, the drawings in the following description are only some embodiments of the disclosure, and for those of ordinary skills in the art, other drawings may be obtained according to these drawings under the premise of not paying out creative work.

FIG. 1 is a structural schematic diagram of a display substrate according to an embodiment of the disclosure;

FIG. 2 is a schematic diagram of charging a capacitor according to an embodiment of the disclosure;

FIG. 3a is a structural schematic diagram of a display substrate according to an embodiment of the disclosure;

FIG. 3b is a structural schematic diagram of a display substrate according to another embodiment of the disclosure;

FIG. 3c is a structural schematic diagram of a display substrate according to yet another embodiment of the disclosure;

FIG. 4 is a structural schematic diagram of a first electrode according to an embodiment of the disclosure;

FIG. 5 is a structural schematic diagram of a first electrode according to another embodiment of the disclosure; and

FIG. 6 is a flow chart of a method for manufacturing a display substrate according to an embodiment of the disclosure.

### REFERENCE SIGNS

1—basal substrate; 2—first electrode; 21—first electrode subunit; 22—signal transmission line; 3—middle frame; 4—second electrode; 5—organic light emitting device; 51—bottom electrode layer; 52—top electrode layer; 6—thin film transistor; 60—active layer; 61—first gate layer; 62—source-drain layer; 63—second gate layer.

### DETAILED DESCRIPTION OF THE DISCLOSURE

In the following, the technical solutions in embodiments of the disclosure will be described clearly and completely in connection with the drawings in the embodiments of the disclosure. Obviously, the described embodiments are only part of the embodiments of the disclosure, and not all of the embodiments.

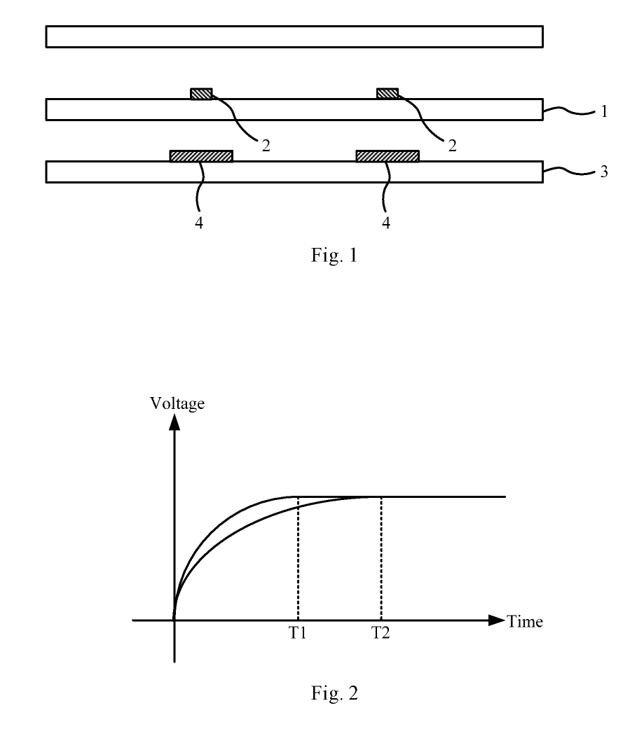

As shown in FIG. 1, according to an embodiment of the present disclosure, the display substrate includes a basal substrate 1, a first electrode 2, a middle frame 3 and a second electrode 4. The first electrode 2 is disposed on the basal substrate 1, and the first electrode 2 can be deformed by a detectable touch operation (e.g., pressure). The middle frame 3 is disposed on a side of the basal substrate 1 departing from the first electrode 2. The second electrode 4 is disposed between the middle frame 3 and the basal substrate 1, forming a capacitor with the first electrode 2. The capacitance of the capacitor is variable based on deformation of the first electrode 2.

In the solution of the embodiment, the second electrode is arranged on the middle frame. The first electrode and the second electrode form a capacitor as a pressure sensor. Therefore, the pressure sensor can be integrated into the display substrate, and the space occupied by the pressure sensor in the display substrate is reduced.

An implementation for sensing the touch pressure according to an embodiment is as follows.

When a finger touches the surface of the display substrate, the coupling capacitance between the first electrode and the second electrode is C1. When a square wave signal for touch control is input to C1, due to the RC load of C1, the charging time of C1 is T1. When the finger presses the display substrate, the distance between the first electrode and the second electrode becomes smaller. C1 is thus increased, the charging time of C1 is changed, and the charging time is T2 (as shown in FIG. 2). Then the processing unit calculates the magnitude of the touch pressure based on the change of the charging time.

Of course, in addition to the above mentioned implementation, the touch pressure can also be calculated directly based on the change of the capacitance C1. For an LCD display substrate, the middle frame may be a frame for fixing the light guide plate in the backlight. For an OLED display substrate, the middle frame may be a frame for fixing the basal substrate. For example, the display substrate in the present embodiment can be applied to a mobile phone, the middle frame can be used for fixing the basal substrate, and the middle frame can also be used for accommodating and fixing elements such as the driving circuit of the pixel unit and the graphics processor (GPU). In addition, it should be noted that the structure in FIG. 1 is only an example, the insulating layer and passivation layer between the electrode layers are not shown. For example, the bottom electrode of the organic light emitting device can only contact the drain of the thin film transistor. Some structures such as an organic light emitting layer can also be arranged between the bottom electrode and the top electrode.

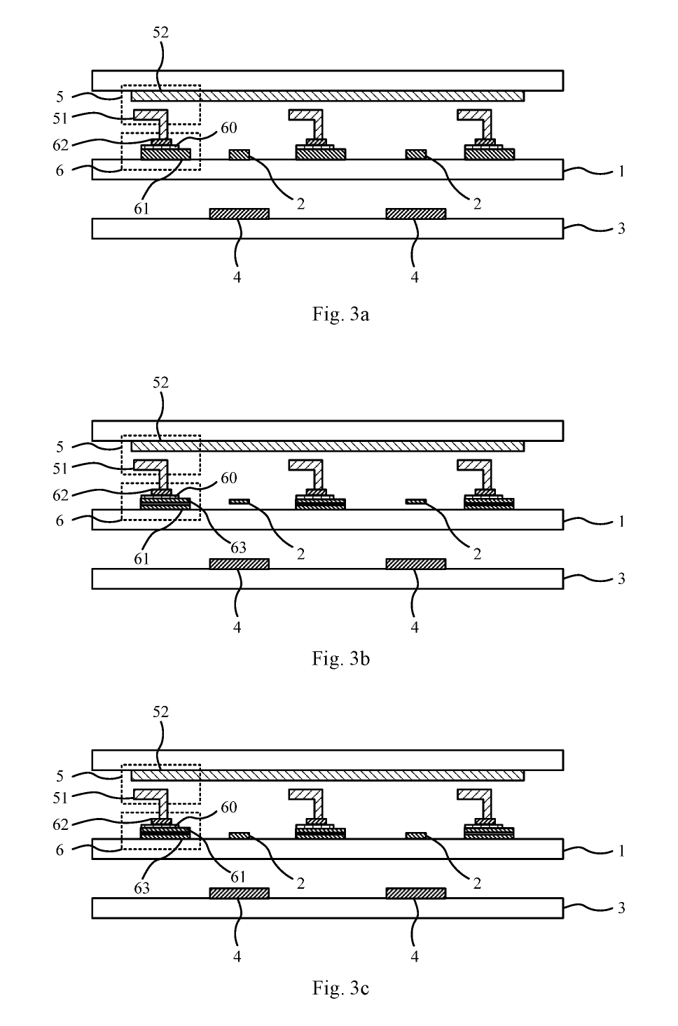

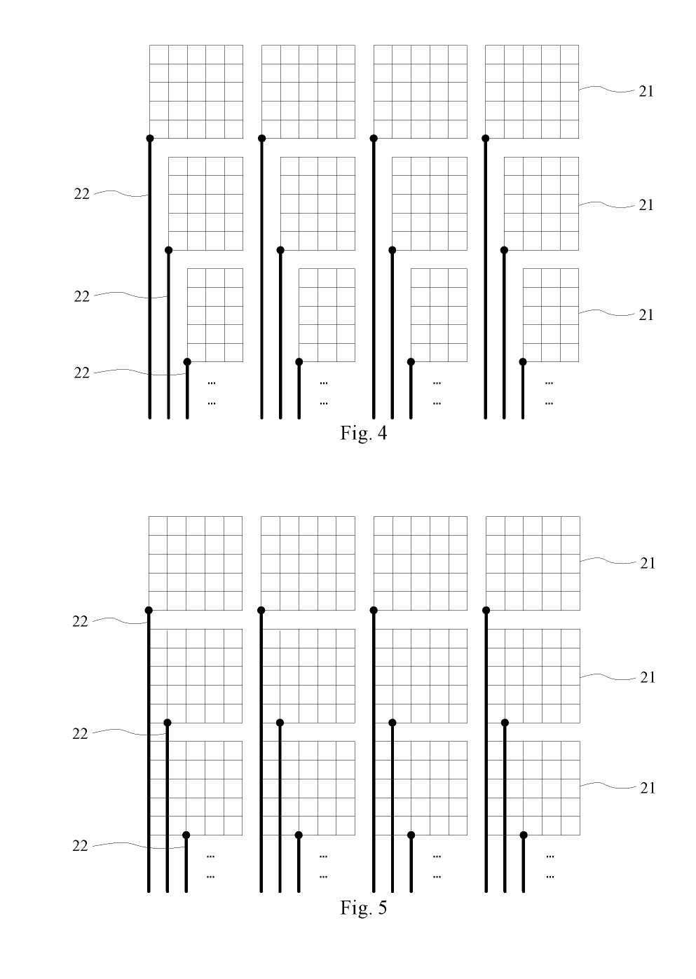

As shown in FIG. 3a, in certain exemplary embodiments, the display substrate further includes an organic light emitting device 5 and a thin film transistor 5 for driving the organic light emitting device disposed on the basal substrate 1. The organic light emitting device 5 includes a bottom electrode layer 51 and a top electrode layer 52. The thin film transistor 6 includes a first gate layer 61, a second gate layer (not shown in FIG. 3a) and a source-drain layer 62. The first electrode 2 is formed in the same layer with any one of the first gate layer 61, the second gate layer, the source-drain layer 62 and the bottom electrode layer 51.

In some embodiments, the display substrate can be an organic light emitting display substrate, and the first electrode can be formed in the same layer with any one of the layers in the structure. Therefore, it is unnecessary to form the first electrode separately, simplifying the fabrication process. However, the first electrode should be kept away from the original wires in the layer. In addition, since the top electrode is generally planar, and the remaining area of the layer is relatively small, the first electrode and the top electrode are generally formed in different layers.

In certain exemplary embodiments, the display substrate further includes a liquid crystal layer disposed on the basal substrate. A thin film transistor, a pixel electrode layer and a common electrode layer for controlling the liquid crystal layer are disposed on the basal substrate. The thin film transistor includes a gate layer and a source-drain layer. The first electrode is formed in the same layer with any one of the gate layer, the source-drain layer and the pixel electrode layer.

In some embodiments, the display substrate can be an LCD display substrate. The structure of the thin film transistor is similar to that in FIG. 3a. The difference is that no organic light emitting device is included, and a pixel electrode, a liquid crystal layer and a common electrode are arranged above the thin film transistor. The first electrode can be formed in the same layer with any one of the layers in the structure except the common electrode. Therefore, it is unnecessary to form the first electrode separately, simplifying the fabrication process. However, the first electrode should be kept away from the original wires in the layer.

In certain exemplary embodiments, the first electrode 2 and the second gate layer are formed in the same layer.

Since the number of wires in the second gate layer is relatively small, the first electrode can be In certain exemplary embodiments formed in the second gate layer to increase the area occupied by the first electrode. For example, the pixel circuit applies a 6T1C (6 transistors and 1 capacitor Cₛₜ) structure, then the second gate layer and the first gate layer are respectively two layers of the capacitor Cₛₜ. For example, as shown in FIG. 3b, the second gate layer 63 can be arranged between the first gate layer 61 and the active layer 60. As shown in FIG. 3c, the second gate layer 63 can also be arranged between the first gate layer 61 and the basal substrate 1.

As shown in FIG. 4, certain exemplary embodiments, the first electrode 2 includes a plurality of first electrode subunits 21. Each first electrode subunit 21 has a grid shape.

In some embodiments, the first electrode includes a plurality of first electrode subunits, so that the plurality of first electrode subunits can be distributed uniformly and sense pressure variation on each position more accurately.

The first electrode subunit has a grid shape so as to reduce the alignment area of the first electrode subunit and other layers, thereby reducing the coupling capacitance and improving the display performance.

In certain exemplary embodiments, the second electrode 4 includes a plurality of second electrode subunits. Each second electrode subunit has the same area and shape as a corresponding first electrode subunit 21. The second electrode subunits and the first electrode subunits can be arranged according to this embodiment. The alignment area of the second electrode and the first electrode can thus be increased, so as to improve the capacitance formed by the second electrode and the first electrode, thereby sensitively monitoring the change of the capacitance.

In certain exemplary embodiments, the first electrode 2 further includes a plurality of signal transmission lines 22 connected with the plurality of first electrode subunits 21 in one-to-one correspondence. The signal transmission lines 22 are disposed in the same layer with the first electrode 2 and extend along a first direction. The areas of the first electrode subunits 21 gradually decrease along the first direction, thereby providing layout space for the signal transmission lines 22. As shown in FIG. 4, the first direction can be downward in a vertical direction. In fact, the extending direction of the signal transmission line can be arranged according to the requirements, and the plurality of first electrode subunits can be arranged/formed based on the extending direction.

In some embodiments, the first electrode subunits and the signal transmission lines can be arranged in the same layer, thereby simplifying the manufacturing process.

As shown in FIG. 5, in certain exemplary embodiments, the first electrode 2 further includes a plurality of signal transmission lines 22 connected with the plurality of first electrode subunits 21 in one-to-one correspondence. The signal transmission line 22 and the first electrode 2 are in different layers. The plurality of first electrode subunits 21 have the same area and the same shape.

In some embodiments, the first electrode subunit and the signal transmission line can be arranged in different layers, so that the signal transmission line will not affect the arrangement of the first electrode subunit. Therefore, the plurality of first electrode subunits can be arranged to have the same area, so as to ensure that the capacitors formed by the first electrode and the second electrode on the positions of the display substrate are the same, thereby ensuring the induction sensitivity and accuracy for touch operation.

In certain exemplary embodiments, the display substrate further includes a processing unit generating a touch control signal based on a capacitance variation of the capacitor.

An embodiment of the present disclosure further provides a display device. The display device includes the display substrate according to any one of the above mentioned embodiments.

It should be noted that the display device can be any product or component with display function, such as LCD panel, electronic paper, OLED panel, mobile phone, tablet computer, TV, notebook computer, digital photo frame and navigator.

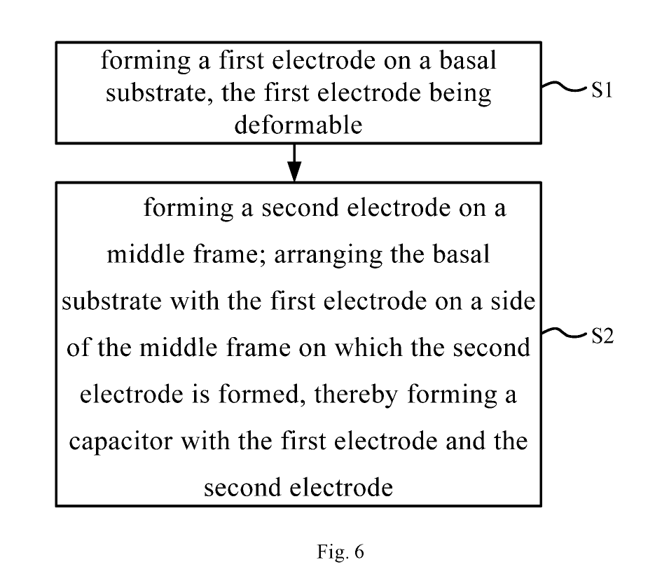

As shown in FIG. 6, an embodiment of the present disclosure further provides a method for manufacturing a display substrate. The method includes the following steps.

S1, forming a first electrode on a basal substrate, the first electrode being deformable. The first electrode can be deformed by a detectable touch operation (e.g., pressure).

S2, forming a second electrode on a middle frame; arranging the basal substrate with the first electrode on a side of the middle frame on which the second electrode is formed, thereby forming a capacitor with the first electrode and the second electrode.

In certain exemplary embodiments, the method further includes forming an organic light emitting device and a thin film transistor for driving the organic light emitting device on the basal substrate. The organic light emitting device includes a bottom electrode layer and a top electrode layer. The thin film transistor includes a first gate layer, a second gate layer and a source-drain layer. The step of forming the first electrode includes: forming the first electrode when forming any one of the first gate layer, the second gate layer, the source-drain layer and the bottom electrode layer.

In certain exemplary embodiments, the method further includes forming a thin film transistor, a pixel electrode layer and a common electrode layer on the basal substrate for controlling a liquid crystal layer. The thin film transistor includes a gate layer and a source-drain layer. The step of forming the first electrode includes: forming the first electrode when forming any one of the gate layer, the source-drain layer and the pixel electrode layer.

In certain exemplary embodiments, the step of forming the first electrode includes forming a plurality of first electrode subunits. The step of forming the second electrode includes forming a plurality of second electrode subunits. The positions of the second electrode subunits are one-to-one corresponding to the positions of the first electrode subunits.

In certain exemplary embodiments, the step of forming the first electrode includes forming a plurality of second electrode subunits with grid shapes.

In certain exemplary embodiments, the method further includes: in a layer different from the first electrode subunits, forming a plurality of signal transmission lines connected with the plurality of first electrode subunits in one-to-one correspondence. The step of forming the first electrode further includes forming the plurality of first electrode subunits having the same area and the same shape.

In certain exemplary embodiments, the method further includes: forming a plurality of signal transmission lines in the same layer with the first electrode subunits. The plurality of signal transmission lines are connected with the plurality of first electrode subunits in one-to-one correspondence and extend along a first direction. The step of forming the first electrode further includes forming the plurality of first electrode subunits. The areas of the first electrode subunits gradually decrease along the first direction, thereby providing layout space for the signal transmission lines.

The forming processes adopted in the above mentioned procedure can include: for example, film-forming process such as deposition and sputtering, and composition process such as etching.

The technical solutions of the embodiments of the disclosure have been explained in detail in combination with the drawings. The touch sensor can be arranged separately. Alternatively, the structure of the display substrate can be modified so that the touch sensor can be arranged in the display substrate. According to the solution of the embodiments, the second electrode is arranged on the middle frame. The first electrode and the second electrode form a capacitor as a pressure sensor. Therefore, the pressure sensor can be integrated into the display substrate, and the space occupied by the pressure sensor in the display substrate is reduced.

It should be noted that, in the drawings, the dimensions of the layers and areas may be exaggerated for clarity of the illustration. Moreover, it should be understood that when an element or layer is referred to as “on” another element or layer, it may be directly on another element, and an intermediate layer may also exist. In addition, it should be understood that when an element or layer is referred to as “under” another element or layer, it may be directly under another element, and one or more intermediate layers or elements may also exist. Furthermore, it should be understood when a layer or element is referred to as “between” two layers or two elements, it may be the only layer or element between these two layers or two elements, and one or more intermediate layers or elements may also exist. Throughout the disclosure, similar reference signs refer to similar elements.

In the specification and claims, the terms “first” and “second” are used only for the purpose of description, and not to indicate or imply relative importance. The term “plurality” refers to two or more unless explicitly specified.

The above embodiments are only used for explanations rather than limitations to the present disclosure, the ordinary skilled person in the related technical field, in the case of not departing from the spirit and scope of the present disclosure, may also make various modifications and variations, therefore, all the equivalent solutions also belong to the scope of the present disclosure.

1. A display substrate comprising:
a basal substrate;
a first electrode disposed on the basal substrate, the first electrode being deformable;
a middle frame disposed on a side of the basal substrate departing from the first electrode; and
a second electrode disposed between the middle frame and the basal substrate, forming a capacitor with the first electrode; the capacitance of the capacitor being variable based on deformation of the first electrode.

2. The display substrate according to claim 1, further comprising:
an organic light emitting device and a thin film transistor for driving the organic light emitting device disposed on the basal substrate;
wherein the organic light emitting device comprises a bottom electrode layer and a top electrode layer; the thin film transistor comprises a first gate layer, a second gate layer and a source-drain layer;
and wherein the first electrode is formed in the same layer with any one of the first gate layer, the second gate layer, the source-drain layer and the bottom electrode layer.

3. The display substrate according to claim 1, further comprising:
a liquid crystal layer disposed on the basal substrate; a thin film transistor, a pixel electrode layer and a common electrode layer for controlling the liquid crystal layer; the thin film transistor comprising a gate layer and a source-drain layer;
wherein the first electrode is formed in the same layer with any one of the gate layer, the source-drain layer and the pixel electrode layer.

4. The display substrate according to claim 2, wherein the first electrode and the second gate layer are formed in the same layer.

5. The display substrate according to claim 2, wherein the first electrode comprises a plurality of first electrode subunits, and each first electrode subunit has a grid shape.

6. The display substrate according to claim 5, wherein the second electrode comprises a plurality of second electrode subunits, each second electrode subunit has the same area and shape as a corresponding first electrode subunit.

7. The display substrate according to claim 5, wherein the first electrode further comprises a plurality of signal transmission lines connected with the plurality of first electrode subunits in one-to-one correspondence;
wherein the signal transmission lines are disposed in the same layer with the first electrode and extend along a first direction; the areas of the first electrode subunits gradually decrease along the first direction, thereby providing layout space for the signal transmission lines.

8. The display substrate according to claim 5, wherein the first electrode further comprises a plurality of signal transmission lines connected with the plurality of first electrode subunits in one-to-one correspondence;
wherein the signal transmission line and the first electrode are in different layers, and the plurality of first electrode subunits have the same area and the same shape.

9. The display substrate according to claim 1, further comprising:
a processing unit generating a touch control signal based on a capacitance variation of the capacitor.

10. A display device comprising the display substrate according to claim 1.

11. A method for manufacturing a display substrate, comprising:
forming a first electrode on a basal substrate, the first electrode being deformable; and
forming a second electrode on a middle frame; arranging the basal substrate with the first electrode on a side of the middle frame on which the second electrode is formed, thereby forming a capacitor with the first electrode and the second electrode.

12. The method according to claim 11, further comprising:
forming an organic light emitting device and a thin film transistor for driving the organic light emitting device on the basal substrate;
the organic light emitting device comprising a bottom electrode layer and a top electrode layer; the thin film transistor comprising a first gate layer, a second gate layer and a source-drain layer;
wherein the step of forming the first electrode comprises:
forming the first electrode when forming any one of the first gate layer, the second gate layer, the source-drain layer and the bottom electrode layer.

13. The method according to claim 11, further comprising:
forming a thin film transistor, a pixel electrode layer and a common electrode layer on the basal substrate for controlling a liquid crystal layer; the thin film transistor comprising a gate layer and a source-drain layer;
wherein the step of forming the first electrode comprises:
forming the first electrode when forming any one of the gate layer, the source-drain layer and the pixel electrode layer.

14. The method according to claim 12 or 13, wherein the step of forming the first electrode comprises forming a plurality of first electrode subunits;
and wherein the step of forming the second electrode comprises forming a plurality of second electrode subunits, the positions of the second electrode subunits are one-to-one corresponding to the positions of the first electrode subunits.

15. The method according to claim 14, wherein the step of forming the first electrode comprises forming a plurality of second electrode subunits with grid shapes.

16. The method according to claim 14, further comprising:
in a layer different from the first electrode subunits, forming a plurality of signal transmission lines connected with the plurality of first electrode subunits in one-to-one correspondence;
wherein the step of forming the first electrode further comprises forming the plurality of first electrode subunits having the same area and the same shape.

17. The method according to claim 14, further comprising:
forming a plurality of signal transmission lines in the same layer with the first electrode subunits; the plurality of signal transmission lines being connected with the plurality of first electrode subunits in one-to-one correspondence and extending along a first direction;
wherein the step of forming the first electrode further comprises forming the plurality of first electrode subunits; the areas of the first electrode subunits gradually decreasing along the first direction, thereby providing layout space for the signal transmission lines.

18. The display device according to claim 10, further comprising:
an organic light emitting device and a thin film transistor for driving the organic light emitting device disposed on the basal substrate;
wherein the organic light emitting device comprises a bottom electrode layer and a top electrode layer; the thin film transistor comprises a first gate layer, a second gate layer and a source-drain layer;
and wherein the first electrode is formed in the same layer with any one of the first gate layer, the second gate layer, the source-drain layer and the bottom electrode layer.

19. The display device according to claim 10, further comprising:
a liquid crystal layer disposed on the basal substrate; a thin film transistor, a pixel electrode layer and a common electrode layer for controlling the liquid crystal layer; the thin film transistor comprising a gate layer and a source-drain layer;
wherein the first electrode is formed in the same layer with any one of the gate layer, the source-drain layer and the pixel electrode layer.

20. The display device according to claim 18, wherein the first electrode comprises a plurality of first electrode subunits, and each first electrode subunit has a grid shape.
